(19) United States
(12) Patent Application Publication
(10) Pub. No.: US 2007/0033456 A1
(43) Pub. Date: Feb. 8, 2007

(54) Integrated circuit test system and associated methods

(76) Inventor: Un-Sang Yu, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/455,710

(22) Filed: Jun. 20, 2006

(30) Foreign Application Priority Data
Jul. 21, 2005 (KR) 2005-66376

(51) Int. Cl. G01R 31/28

(52) U.S. Cl. 714/724

(57) ABSTRACT

An integrated circuit chip test system comprises a reference chip adapted to generate original test data, and a test target chip adapted to receive and process the original test data to produce processed test data. The test target chip returns the processed test data to the reference chip, and the reference chip detects the presence of functional defects in the test target chip by comparing the test data with the processed test data.

### BACKGROUND OF THE INVENTION

1. Field of the Invention

Embodiments of the invention relate generally to test systems for integrated circuit chips. More particularly, embodiments of the invention relate to test systems using a reference chip to reduce the time and cost required to test the integrated circuits chips.

A claim of priority is made to Korean Patent Application No. 2005-66376, filed on Jul. 21, 2005, the disclosure of which is hereby incorporated by reference in its entirety.

2. Description of Related Art

Integrated circuit (IC) design and manufacturing techniques are imperfect. As a result, IC chips are often manufactured with defects that can cause the chips to fail or malfunction. To prevent defective IC chips from being delivered to end users, IC chip manufacturers perform extensive testing on their chips before sending them to market.

The testing of an IC chip typically takes the form of applying stimulus signals to the chip and measuring the chip's responses to the stimulus signals. In general, this testing tends to require sophisticated electronic test equipment such as automatic test equipment (ATE) to apply the stimulus signals. The analysis of the chip's responses to the stimulus signals is often carried out by a computer or similar apparatus.

Unfortunately, as the integration density of IC chips continues to increase, the complexity and difficulty of testing the chips tends to increase accordingly. As a result, testing procedures have come to occupy a significant portion of the cost of producing IC chips. Therefore, in order to increase the profitability of producing IC chips, manufacturers would like to develop cheaper, more reliable methods of testing IC chips.

Among the more costly aspects of testing complicated IC chips is the cost of purchasing ATE equipment. For example, to test a high speed system such as a universal serial bus (USB), a serial advanced technology attachment (SATA) used in hard disc drivers (HDD), or fibre channel SerDes (Serializer/Deserializer) used in servers, the ATE must include an expensive high speed data generator to generate the stimuli signals (test signals). In addition to the component costs, ATE can also take a long time to set up, causing delays in the eventual mass production of IC chips.

### SUMMARY OF THE INVENTION

In order to reduce the overall time and expense required by conventional IC test systems, embodiments of the invention provide test systems that use a reference chip rather than expensive automated test equipment.

According to one embodiment of the invention, a test system for an integrated circuit chip comprises a reference chip generating original test data, and a test target chip receiving and processing the original test data to produce processed test data. The reference chip returns the processed test data to the reference chip, and the reference chip detects the presence or absence of a functional defect in the test target chip by comparing the test data with the processed test data.

According to another embodiment of the invention, a test system comprises a reference chip generating original test data, a test target chip receiving and processing the original test data to produce processed test data and returning the processed test data to the reference chip, and a comparator adapted to detect the presence or absence of a functional defect in the test target chip by comparing the original test data with the processed test data.

According to another embodiment of the invention, a method of testing a test target chip is provided. The method comprises generating original test data by operation of a reference chip, receiving the original test data in the test target chip, processing the original test data to produce processed test data, and returning the test data to the reference chip, and, detecting a functional defect in the test target chip by comparing the original test data with the processed test data in the reference chip.

According to another embodiment of the invention, a method of testing a test target chip comprises generating original test data by operation of a reference chip, receiving the original test data in the test target chip, processing the original test data to produce processed test data, and returning the processed test data to the reference chip, and detecting a functional defect of the test target chip by comparing the original test data with the processed test data using a comparator.

### BRIEF DESCRIPTION OF THE DRAWINGS

The invention is described below in relation to several embodiments illustrated in the accompanying drawings. Throughout the drawings like reference numbers indicate like exemplary elements, components, or steps. In the drawings:

FIG. 1 is a block diagram of a test system according to one embodiment of the invention;

FIG. 2 is a block diagram of a test system according to another embodiment of the invention;

FIG. 3 is a block diagram of a test system according to yet another embodiment of the invention;

FIG. 4 is a block diagram of a test system according to still another embodiment of the invention;

FIG. 5 is a block diagram illustrating a system for testing a plurality of chips in accordance with an embodiment of the invention; and,

FIG. 6 is a block diagram illustrating another system for testing a plurality of chips in accordance with another embodiment of the invention.

### DESCRIPTION OF EXEMPLARY EMBODIMENTS

Exemplary embodiments of the invention are described below with reference to the corresponding drawings. These embodiments are presented as teaching examples. The actual scope of the invention is defined by the claims that follow.

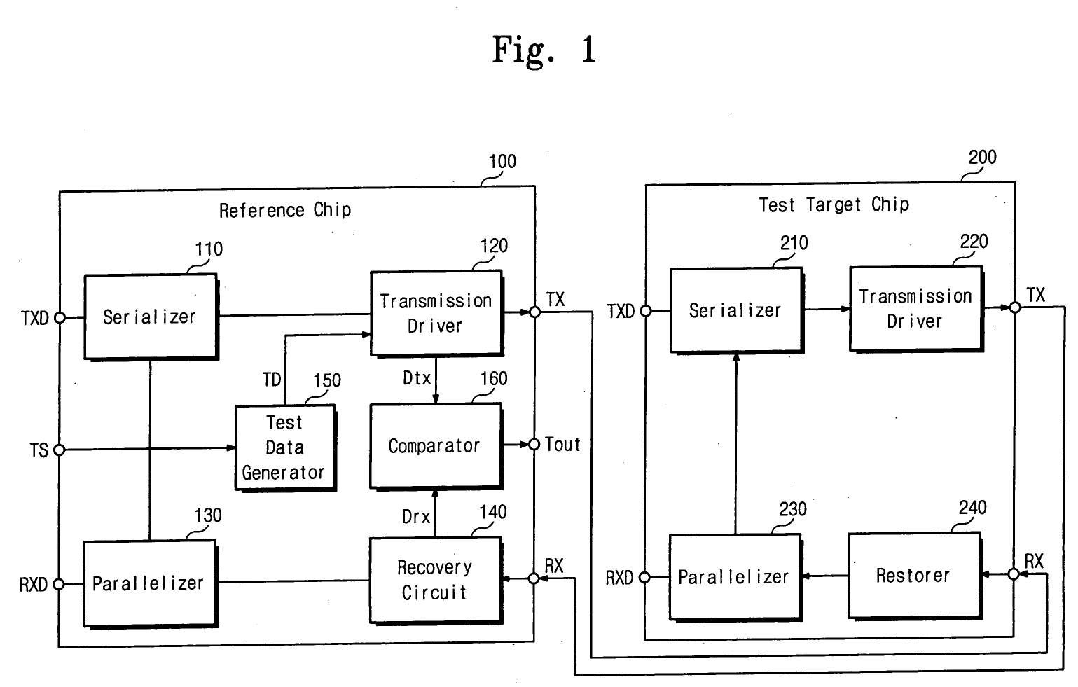

FIG. 1 is a block diagram illustrating an integrated circuit (IC) test system according to one embodiment of the invention. Referring to FIG. 1, the test system comprises a reference chip 100 for verifying an operation of a test target chip 200. Reference chip 100 comprises input and output terminals, including a parallel data input terminal TXD, a parallel data output terminal RXD, a serial data output terminal TX, a serial data input terminal RX, a test control terminal TS, and a test output terminal Tout. Reference chip 100 further comprises a serializer 110, a transmission (or output) driver 120, a parallelizer 130, a recovery circuit 140, a test data generator 150, and a comparator 160.

Serializer 110 transforms parallel data into serial data. Serializer 110 receives parallel data from parallel data input terminal TXD or parallelizer 130 and transforms the parallel data into serial data to be transferred to transmission driver 120.

Transmission driver 120 receives the serial data from serializer 110 and controls an output operation of the serial data through serial data output terminal TX. Transmission driver 120 also receives test data TD from test data generator 150 and outputs test data TD to test target chip 200 and comparator 160 as output test data Dtx. Comparator 160 receives and temporarily stores output test data Dtx.

Test data TD is used to test test target chip 200. Test data generator 150 begins to generate test data TD in response to a control signal supplied through test control terminal TS. Preferably, test data generator 150 comprises a plurality of switches for creating test data patterns to form test data TD.

Parallelizer 130 transforms serial data into parallel data. Parallelizer 130 generates the parallel data from serial data received from recovery circuit 140 and sends the parallel data to parallel data output terminal RXD or serializer 110.

Recovery circuit 140 receives input data through serial data input terminal Rx and recovers input test data Drx based on the input data. Recovery circuit 140 then applies input test data Drx to comparator 160.

Comparator 160 compares output test data Dtx from transmission driver 120 with input test data Drx. Output test data Dtx is test data input to test target chip 200, and input test data Drx is data produced by test target chip 200 through performing operations on output test data Dtx in functional blocks of test target chip 200. If input test data Drx is inconsistent with output test data Dtx, then test target chip 200 has a functional defect. Comparator 160 generates a signal through test output terminal Tout to indicate whether test target chip 200 is functioning correctly or whether it has any functional defects. Test output terminal Tout may be connected to a display unit such as a light emitting diode (LED) to indicate whether test target chip 200 is functioning correctly.

Test target chip 200 of FIG. 1 comprises input/output terminals including as a parallel data input terminal TXD, a parallel data output terminal RXD, a serial data output terminal TX, and a serial data input terminal RX, and test target chip 200 comprises a serializer 210, a transmission driver 220, a parallelizer 230, and a recovery circuit 240. The operational functions of the input/output terminals and blocks in test target chip 200 are as their respective counterparts in reference chip 100.

Serial data input terminal RX of test target chip 200 receives a test data pattern (i.e., test data TD) output through serial data output terminal TX of reference chip 100. Test target chip 200 processes the test data pattern in various functional blocks and then outputs resulting data through its serial data output terminal TX. Reference chip 100 then receives the data output through serial data output terminal TX of test target chip 200 and compares it with output test data Dtx as described above. Where test target chip 200 has a functional defect, the test data pattern will be undesirably modified by the functional blocks. Accordingly the resulting data will vary from desired resulting data, and therefore its comparison with output test data Dtx will provide an indication of the functional defect.

The test system shown in FIG. 1 is also useful to conducting a test operation for characteristics of power, temperature, and noise. For instance, where test target chip 200 is connected to a power supply having a variable power source level, it is possible to test a power supply margin of test target chip 200 by comparing input and output test data Drx and Dtx in reference chip 100. Further, it is also possible to test noise characteristics of test target chip 200 by adding noise to test data TD supplied from reference chip 100 or adjusting the length of a cable connecting reference chip 100 with test target chip 200.

By using reference chip 100, the test system shown in FIG. 1 is able to verify an operation of test target chip 200 at a lower cost than conventional test systems.

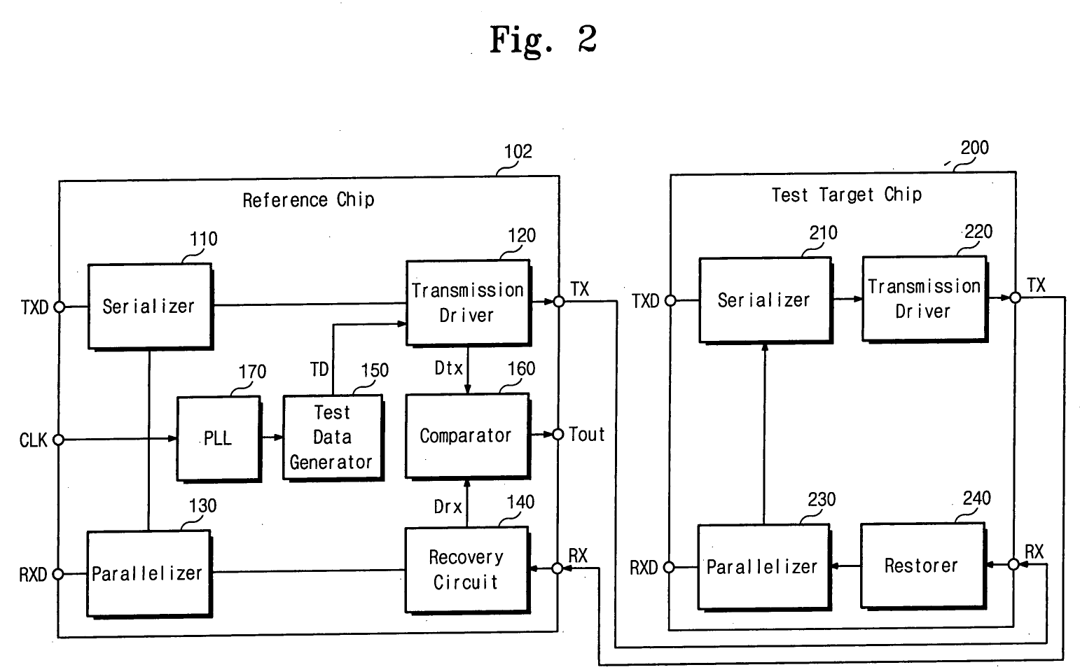

FIG. 2 is a block diagram of a test system according to another embodiment of the invention. In the test system shown in FIG. 2 test data generator 150 of a reference chip 102 begins to generate the test data TD in response to control signals output by a phase-locked loop (PLL) 170 in response to a clock signal supplied through a clock terminal CLK. Operations of the other functional blocks shown in FIG. 2 are as same with those of the test system shown in FIG. 1.

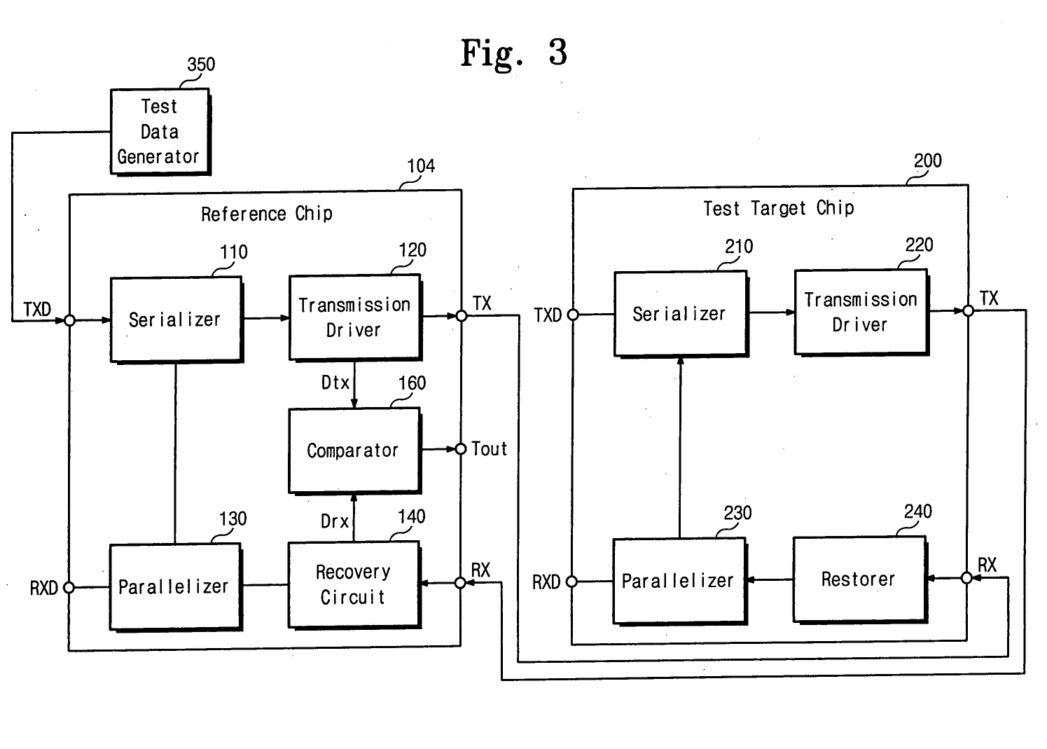

FIG. 3 is a block diagram of a test system according to yet another embodiment of the invention. In the test system shown in FIG. 3, a test data generator 350 is placed outside of a reference chip 104 instead of using test generator 150 as in the test system of FIG. 1. Test data generator 350 preferably comprises switches to generate and apply parallel test data to parallel data input terminal TXD of reference chip 104. The parallel test data input to reference chip 104 is transformed into serial data by serializer 110 and then the serial data is applied to test target chip 200 by way of transmission driver 120. Operations of the other functional blocks shown in FIG. 3 are as same with those of the test system shown in FIG. 1.

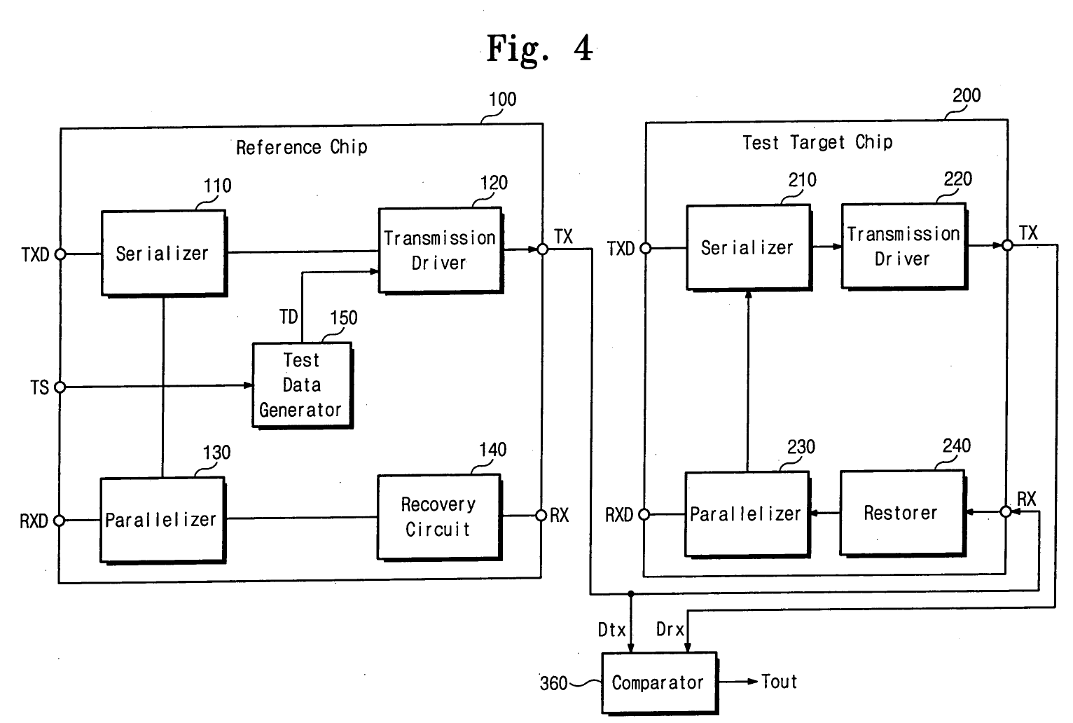

FIG. 4 is a block diagram of a test system according to still another embodiment of the invention. The test system of FIG. 4 comprises a comparator 360 located outside of a reference chip 106. Comparator 360 shown in FIG. 4 compares output test data Dtx from reference chip 106 with input test data Drx from test target chip 200 to verify whether test target chip 200 is functioning correctly.

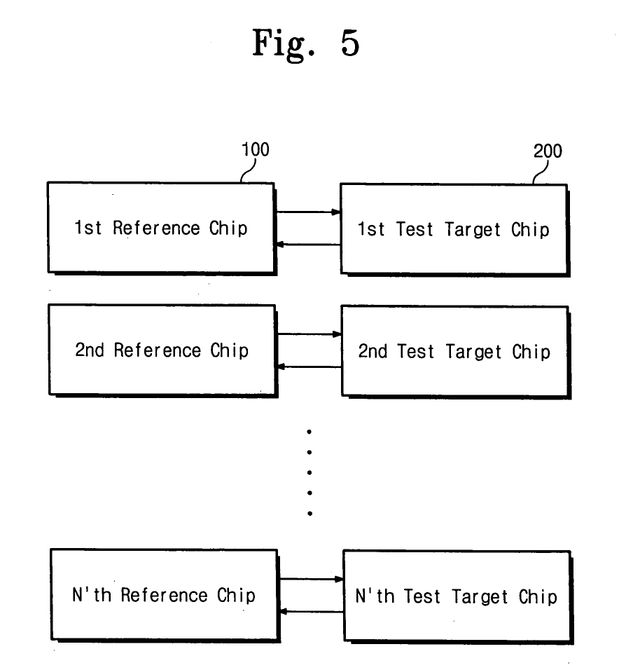

FIG. 5 is a block diagram illustrating a system for testing a plurality of chips in accordance with an embodiment of the invention. The system shown in FIG. 5 tests a plurality of chips by respectively connecting “N” reference chips 100 with “N” test target chips 200. The results of tests performed on the “N” chips can be displayed on a display device such as an LES indicating whether the “N” test target chips 200 function properly.

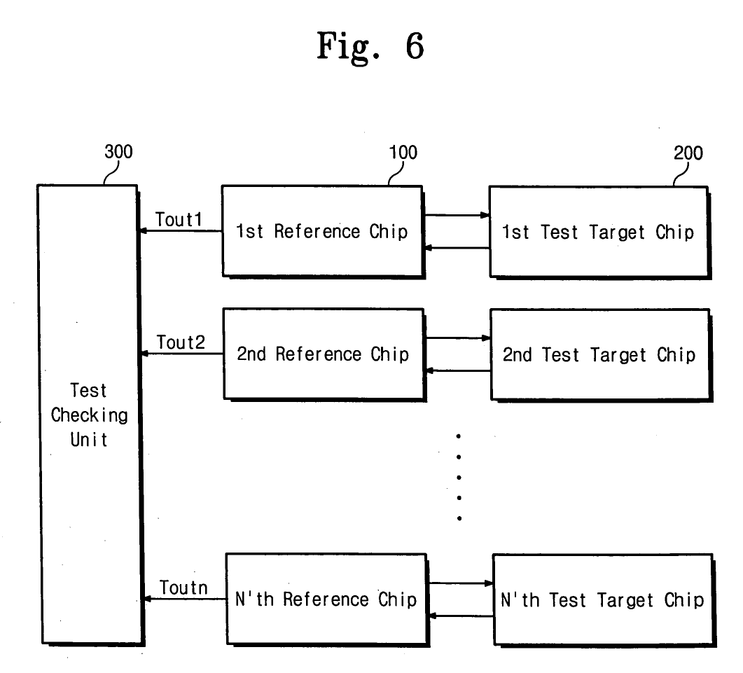

FIG. 6 is a block diagram illustrating another system for testing a plurality of chips in accordance with an embodiment of the invention. The system shown in FIG. 6 comprises a test checking unit 300 for representing (i.e., displaying) test results Tout1 through Toutn output from reference chips 100. Test checking unit 300 preferably comprises visual means such as a picture display, a print-out, or audio output.

As described above, test systems provided by various embodiments of the invention are able to verify a chip operation without an expensive, cumbersome test apparatus. Moreover, embodiments of the invention allow a plurality of reference chips to be used to verify a plurality of test target chips.

The test system can be used to verify the operation of IC chips and various other electronic devices. Without the requirement for additional high-priced test apparatus, the overall cost of manufacturing the electronic devices such as chips can be decreased substantially. In addition, the ability to simultaneously test a plurality of chips also reduces the manufacturing cost.

The foregoing preferred embodiments are teaching examples. Those of ordinary skill in the art will understand that various changes in form and details may be made to the exemplary embodiments without departing from the scope of the present invention as defined by the following claims.

What is claimed:

1. A test system comprising:
a reference chip generating original test data; and,
a test target chip receiving and processing the original test data to produce processed test data, and returning the processed test data to the reference chip,
wherein the reference chip detects the presence or absence of a functional defect in the test target chip by comparing the test data with the processed test data.

2. The test system of claim 1, wherein the reference chip comprises:
a test data generator adapted to generate the original test data; and,
a comparator adapted to compare the original test data with the returned test data.

3. The test system of claim 2, wherein the reference chip comprises a chip that has been verified to function correctly.

4. The test system of claim 2, wherein the comparator determines the test target chip to be free of functional defects when the original test data is identical to the processed test data, and the comparator determines the test target chip to be defective when the original test data is different from the returned test data.

5. The test system of claim 4, wherein the reference chip further comprises a display unit adapted to indicate the presence or absence of functional defects in the test target chip.

6. The test system of claim 5, wherein the display unit comprises a light emitting diode (LED).

7. The test system of claim 2, wherein the test data generator outputs the original test data in response to a control signal supplied from an external source.

8. The test system of claim 2, wherein the test data generator outputs the original test data in response to signal supplied from an internal source.

9. The test system of claim 8, wherein the internal source comprises a phase-lock loop (PLL) controlled by a clock signal supplied from an external source.

10. The test system of claim 1, wherein the test data is serial data.

11. The test system of claim 10, wherein the test target chip transforms the test data into parallel data and serial data in order, and returns the serial data to the reference chip.

12. A test system comprising:
a reference chip generating original test data;
a test target chip receiving and processing the original test data to produce processed test data and returning the processed test data to the reference chip; and,
a comparator adapted to detect the presence or absence of a functional defect in the test target chip by comparing the original test data with the processed test data.

13. The test system of claim 12, wherein the comparator comprises a display unit adapted to represent the presence or absence of a functional defect in the test target chip.

14. The test system of claim 12, wherein the display unit comprises a light emitting diode (LED).

15. A method of testing a test target chip, the method comprising:
by operation of a reference chip, generating original test data;
receiving the original test data in the test target chip, processing the original test data to produce processed test data, and returning the test data to the reference chip; and,
detecting a functional defect in the test target chip by comparing the original test data with the processed test data in the reference chip.

16. The method of claim 15, wherein the test data is generated in response to a control signal from an external source.

17. The method of claim 15, wherein the test data is generated in response to a control signal produced by a phase-lock loop in the reference chip.

18. A method of testing a test target chip, the method comprising:
by operation of a reference chip, generating original test data;
receiving the original test data in the test target chip, processing the original test data to produce processed test data, and returning the processed test data to the reference chip; and,
detecting a functional defect of the test target chip by comparing the original test data with the processed test data using a comparator.

19. The method of claim 18, wherein the comparator resides in the reference chip.

20. The method of claim 18, wherein the original test data is produced by a test data generator in the reference chip in response to a control signal from a phase-lock loop.
